(19) United States
(12) Patent Application Publication
(10) Pub. No.: US 2014/0217578 A1
(43) Pub. Date: Aug. 7, 2014

(54) SEMICONDUCTOR PACKAGE PROCESS AND STRUCTURE THEREOF

(71) Applicant: CHIPBOND TECHNOLOGY CORPORATION, HSINCHU (TW)

(72) Inventors: Lung-Hua Ho, Hsinchu City (TW); Fei-Jain Wu, Hsinchu County (TW); Chih-Ming Kuo, Hsinchu County (TW); Shih-Chieh Chang, Chiayi County (TW); Chia-Jung Tu, Hsinchu County (TW)

(73) Assignee: CHIPBOND TECHNOLOGY CORPORATION, HSINCHU (TW)

(21) Appl. No.: 13/833,347

(22) Filed: Mar. 15, 2013

(30) Foreign Application Priority Data
Feb. 1, 2013 (TW) 102104103

(51) Int. Cl. H01L 23/00

(52) U.S. Cl. CPC H01L 24/17; H01L 24/81
USPC 257/737; 438/107

(57) ABSTRACT

A semiconductor package process includes the following steps, providing a first substrate having a first metal bump, the first metal bump comprises a joint portion having a first softening point; providing a second substrate having a second metal bump having a top surface, a lateral surface and a second softening point, wherein the first softening point is smaller than the second softening point; performing a heating procedure to make the joint portion of the first metal bump become a softened state; and laminating the first substrate on the second substrate to make the second metal bump embedded into the joint portion in the softened state to make the top surface and the lateral surface of the at least one second metal bump being clad extendedly by compressing the joint portion in the softened state.

### FIELD OF THE INVENTION

The present invention is generally related to a semiconductor package process, which particularly relates to the semiconductor package process with high quality and low cost.

### BACKGROUND OF THE INVENTION

The MEMS package technology in modern semiconductor front-end package has developed gradually from combination of bonding and glass frit into metal to metal bonding. However, flux or high-temperature process is not applicable to the rear section in MEMS package technology, therefore resulting in incapability of using surface mounting technology for back-end package. The overall package cost still remains high.

### SUMMARY

The primary object of the present invention is to provide a semiconductor package process, wherein a joint portion is in a softened state by heating the joint portion of a first metal bump of a first substrate. Thereafter laminating the first substrate on a second substrate and making a second metal bump of the second substrate embedded into the joint portion in the softened state to extendedly clad a top surface and a lateral surface of the second metal bump.

A semiconductor package process at least including the following steps: providing a first substrate having a first surface and at least one first metal bump formed on the first surface, the at least one first metal bump comprises a bottom portion and a joint portion having a first softening point, the bottom portion is located between the joint portion and the first substrate; providing a second substrate having a second surface and at least one second metal bump formed on the second surface, the at least one second metal bump comprises a top surface, a lateral surface and a second softening point, wherein the first softening point is smaller than the second softening point; performing a heating procedure to make the joint portion of the at least one first metal bump become a softened state; and making the first surface face toward the second surface and laminating the first substrate on the second substrate to make the at least one second metal bump embedded into the joint portion in the softened state to make the top surface and the lateral surface of the at least one second metal bump being clad extendedly by compressing the joint portion in the softened state, wherein the bottom portion in the softened state is located between the at least one second metal bump and the first substrate.

In the present invention of the semiconductor package process, the joint portion of the at least one first metal bump of the first substrate is in the softened state by performing heating procedure, and thereafter laminating the first substrate on the second substrate to make the at least one second metal bump of the second substrate embedded into the joint portion in the softened state so as to make the joint portion in the softened state being compressed to extendedly clad the top surface and the lateral surface of the at least one second metal bump to form an intermetallic compound so that the first substrate and the second substrate are electrically interconnected without a flux. Therefore, an additional step of washing the flux in the rear section package can be ignored. Besides, the semiconductor package structure enables to bear high temperature higher than lamination temperature under heat process or environmental test therefore achieving package requirement with high quality and low cost.

### DESCRIPTION OF THE DRAWINGS

FIGS. 1A to 1D are cross section diagrams illustrating a semiconductor package structure in accordance with a first embodiment of the present invention.

FIG. 2 is a cross section diagram illustrating a semiconductor package structure in accordance with a second embodiment of the present invention.

FIG. 3 is a cross section diagram illustrating a semiconductor package structure in accordance with a third embodiment of the present invention.

FIG. 4 is a cross section diagram illustrating a semiconductor package structure in accordance with a fourth embodiment of the present invention.

### DETAILED DESCRIPTION OF THE INVENTION

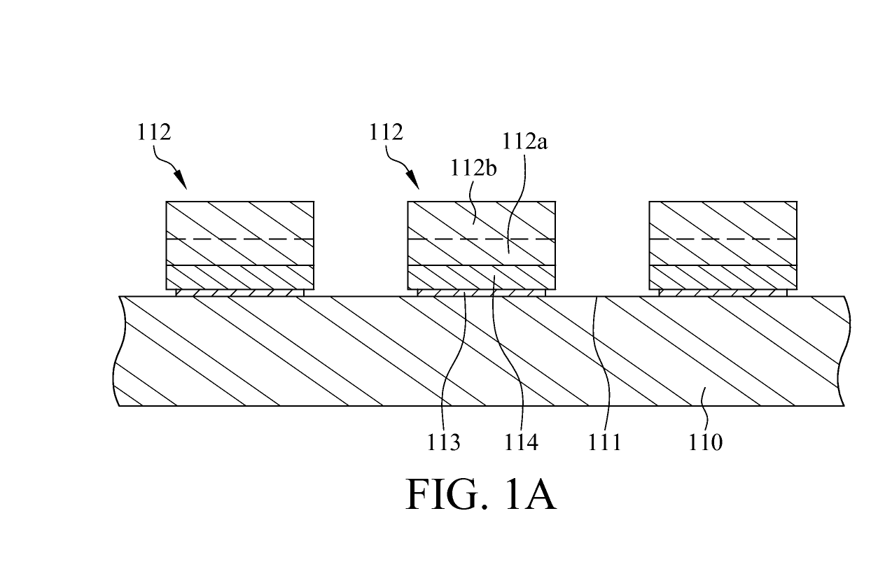

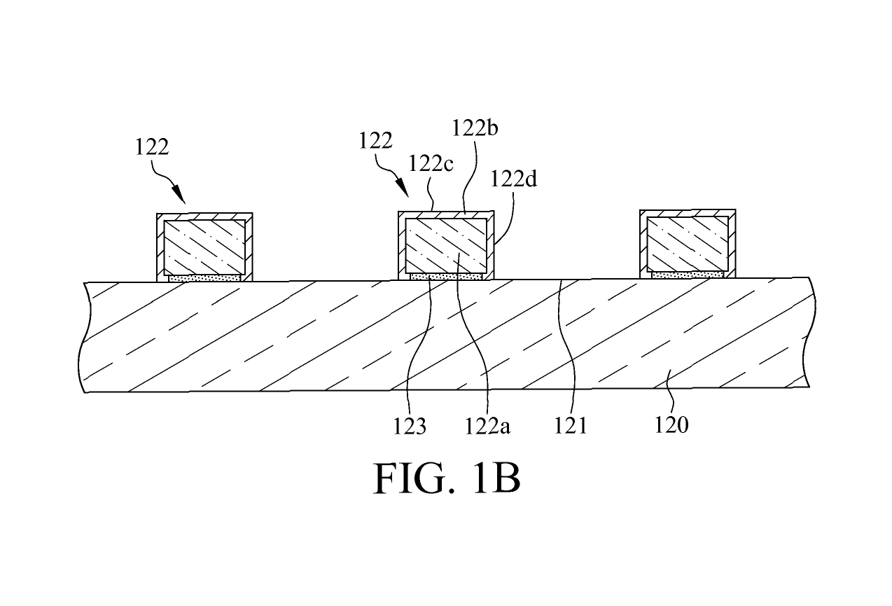

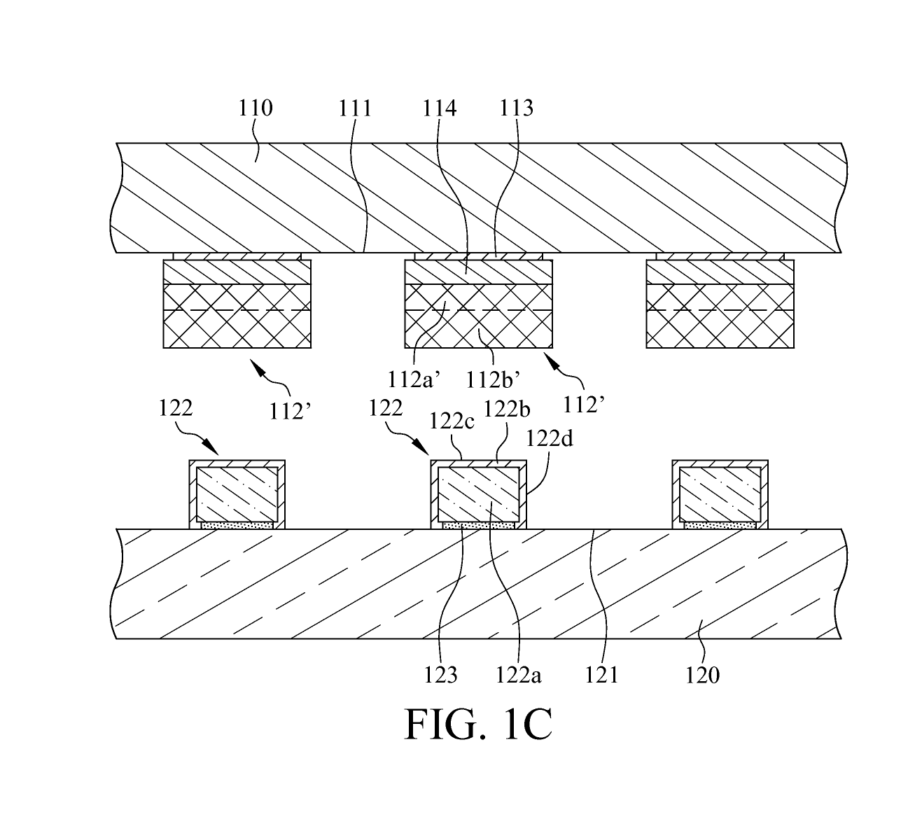

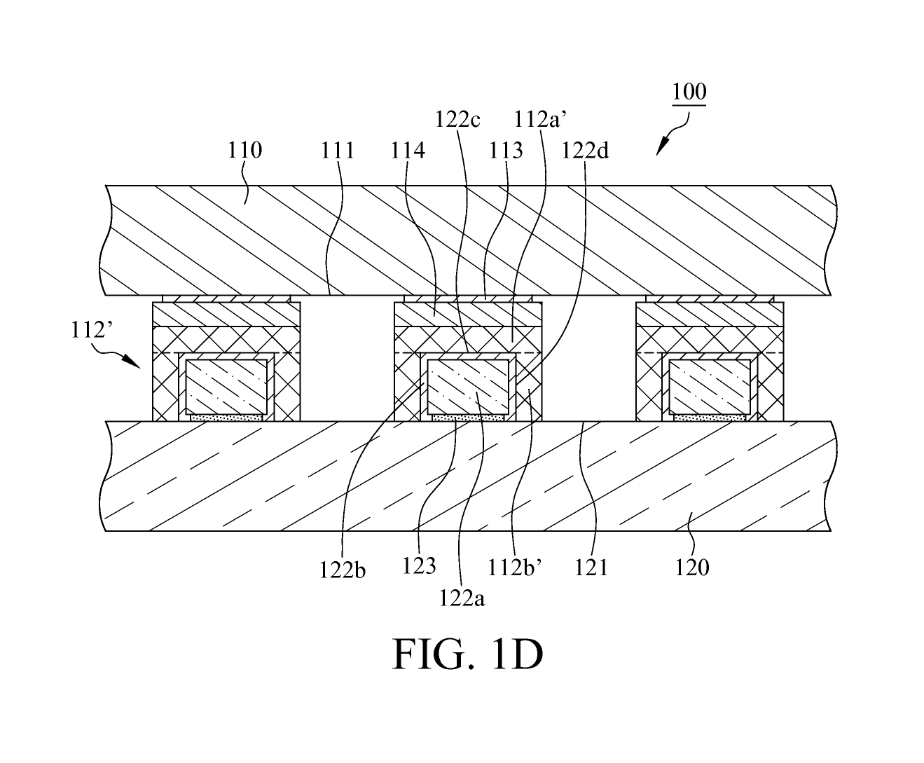

With reference to FIGS. 1A to 1D, a semiconductor package process in accordance with a first embodiment of the present invention includes the steps described as followed: first, referring to FIG. 1A, providing a first substrate 110 having a first surface 111 and at least one first metal bump 112 formed on the first surface 111, in this embodiment, the first substrate 110 further comprises at least one first under bump metallurgy layer 113 formed on the first surface 111 and a connection layer 114, the first metal bump 112 covers the first under bump metallurgy layer 113 and comprises a bottom portion 112a and a joint portion 112b having a first softening point, the bottom portion 112a is located between the joint portion 112b and the first substrate 110, the connection layer 114 is located between the bottom portion 112a of the first metal bump 112 and the first substrate 110 so as to reduce usage volume of the first metal bump 112, wherein the material of the first metal bump 112 is gold, and the material of the connection layer 114 is copper; next, referring to FIG. 1B, providing a second substrate 120 having a second surface 121 and at least one second metal bump 122 formed on the second surface 121, in this embodiment, the second substrate 120 further comprises at least one second under bump metallurgy layer 123 formed on the second surface 121, the second metal bump 122 covers the second under bump metallurgy layer 123 and includes a base layer 122a and a coverage layer 122b covering the base layer 122a, the material of the base layer 122a is copper, the material of the coverage layer 122b is selected from one of tin and tin-silver alloy, the second metal bump 122 comprises a top surface 122c, a lateral surface 122d and a second softening point, wherein the first softening point is smaller than the second softening point, it means the first softening temperature is lower than the second softening temperature; thereafter, referring to FIG. 1C, performing a heating procedure to make the first metal bump 112 become the first metal bump 112′ in a softened state and the joint portion 112b become the joint portion 112b′ in a softened state; eventually, referring to FIG. 1D, making the first surface 111 face toward the second surface 121 and laminating the first substrate 110 on the second substrate 120 to make the second metal bump 122 embedded into the joint portion 112b′ in the softened state of the first metal bump 112′ in the softened state to make the joint portion 112b′ in the softened state being compressed to extendedly clad the top surface 122c and the lateral surface 122d of the second metal bump 122 therefore forming a semiconductor package structure 100, wherein the bottom portion 112a′ in the softened state is located between the second metal bump 122 and the first substrate 110, and the connection layer 114 is located between the bottom portion 112a′ in the softened state and the first substrate 110.

In the present invention, the second metal bump 122 with the second softening point is embedded into the first metal bump 112 with the first softening point by applying heating and lamination procedures, owning to the first softening point of the joint portion 112b smaller than the second softening point of the second metal bump 122, the second metal bump 122 is able to embedded into the joint portion 112b′ in the softened state of the first metal bump 112′ in the softened state after the procedures of heating and lamination, therefore making the top surface 122c and the lateral surface 122d of the at least one second metal bump 122 being clad extendedly by compressing the joint portion 112b′ in the softened state so that the first substrate 110 and the second substrate 120 are electrically interconnected, furthermore, the bottom portion 112a′ in the softened state of the first metal bump 112′ in the softened state is located between the second metal bump 122 and the first substrate 110 to form the semiconductor package structure 100 without a flux so that an additional step of washing the flux can be ignored. The semiconductor package structure 100 enables to bear high temperature higher than lamination temperature under heat process or environmental test therefore achieving package requirement with high quality and low cost.

With reference to FIG. 1D, a semiconductor structure 100 of the present invention at least includes a first substrate 110 and a second substrate 120, the first substrate 110 comprise a first surface 111, at least one first metal bump 112′ in a softened state formed on the first surface 111, at least one first under bump metallurgy layer 113 formed on the first surface 111 and a connection layer 114, wherein the first metal bump 112′ in the softened state covers the first under bump metallurgy layer 113 and comprises a bottom portion 112a′ in the softened state and a joint portion 112b′ in the softened state having a first softening point. The bottom portion 112a′ in the softened state is located between the joint portion 112b′ in the softened state and the first substrate 110, and the connection layer 114 is located between the bottom portion 112a′ in the softened state of the first metal bump 112′ in the softened state and the first substrate 110. In this embodiment, the material of first metal bump 112′ in the softened state is gold, the material of connection layer 114 is copper, and the connection layer 114 is utilized for reducing usage volume of the first metal bump 112′ in the softened state. The second substrate 120 comprises a second surface 121 facing toward the first surface 111, at least one second metal bump 122 formed on the second surface 121 and at least one second under bump metallurgy layer 123 formed on the second surface 121. The second metal bump 122 covers the second under bump metallurgy layer 123 and comprises a top surface 122c, a lateral surface 122d and a second softening point. The first softening point of the joint portion 112b′ in the softened state is smaller than the second softening point of the second metal bump 122. In this embodiment, the second metal bump 122 includes a base layer 122a and a coverage layer 122b covering the base layer 122a, wherein the material of the base layer 122a is copper, and the material of the coverage layer 122b is selected from one of tin or tin-silver alloy. The second metal bump 122 is embedded into the joint portion 112b′ in the softened state of the first metal bump 112′ in the softened state to make the top surface 122c and the lateral surface 122d of the at least one second metal bump 122 being clad extendedly by compressing the joint portion 112b′ in the softened state, and the bottom portion 112a′ in the softened state is located between the second metal bump 122 and the first substrate 110. The usage of flux can be ignored for the semiconductor 100 to achieve electric connection between the first substrate 110 and the second substrate 120 owning to the reason that the joint portion 112b′ in the softened state is compressed to extendedly clad the top surface 122c and the lateral surface 122d of the second metal bump 122, which ignoring an additional step of washing the flux. Particularly, the first metal bump 112′ in the softened state possesses anti-oxidation function when the material of the first metal bump 112′ in the softened state is gold.

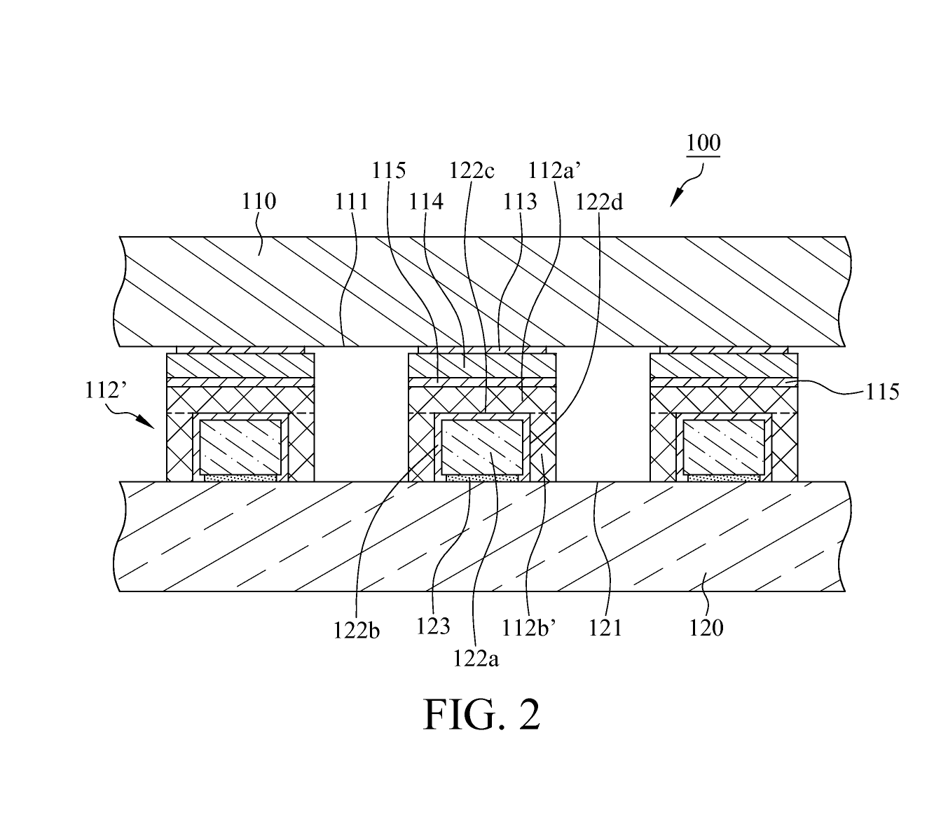

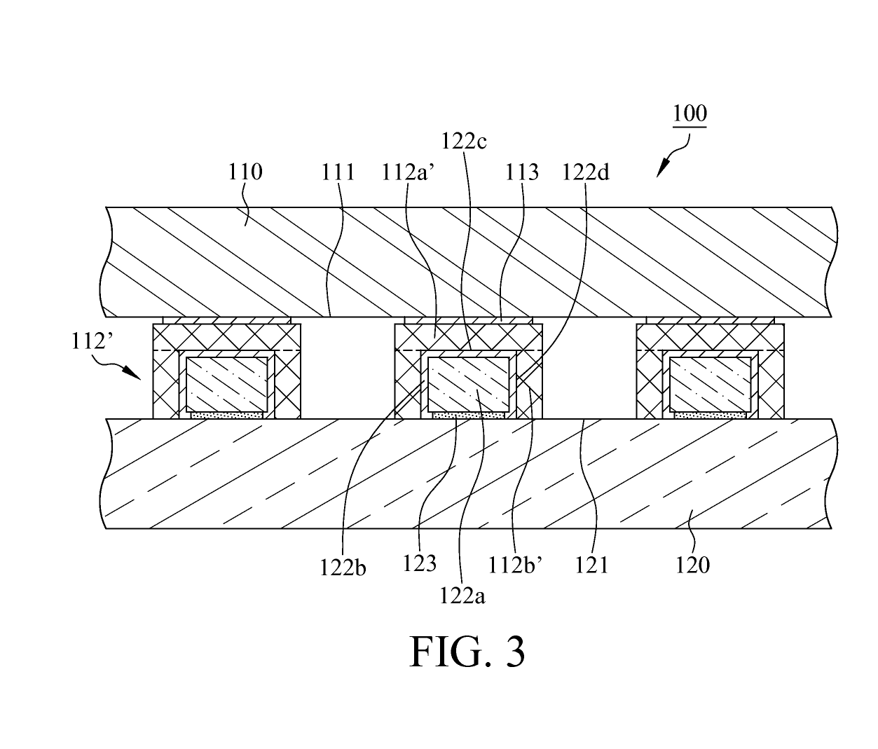

With reference to FIG. 2, a second embodiment of the present invention is illustrated as below. The primary difference between the second embodiment and the first embodiment is that the first substrate 110 further comprises a buffer layer 115 located between the bottom portion 112a′ in the softened state of the first metal bump 112′ in the softened state and the connection layer 114. The material of the buffer layer 115 is selected from nickel to prevent excessive integration between the connection layer 114 and the first metal bump 112′ in the softened state. Or, with reference to FIG. 3, a third embodiment of the present invention is disclosed as below. The primary difference between the third embodiment and the first embodiment is that the first substrate 110 merely comprises the first metal bump 112′ in the softened state and the first under bump metallurgy layer 113. Or, in another embodiment, the second metal bump 122 of the second substrate 120 merely comprises the base layer 122a (not shown in Fig.).

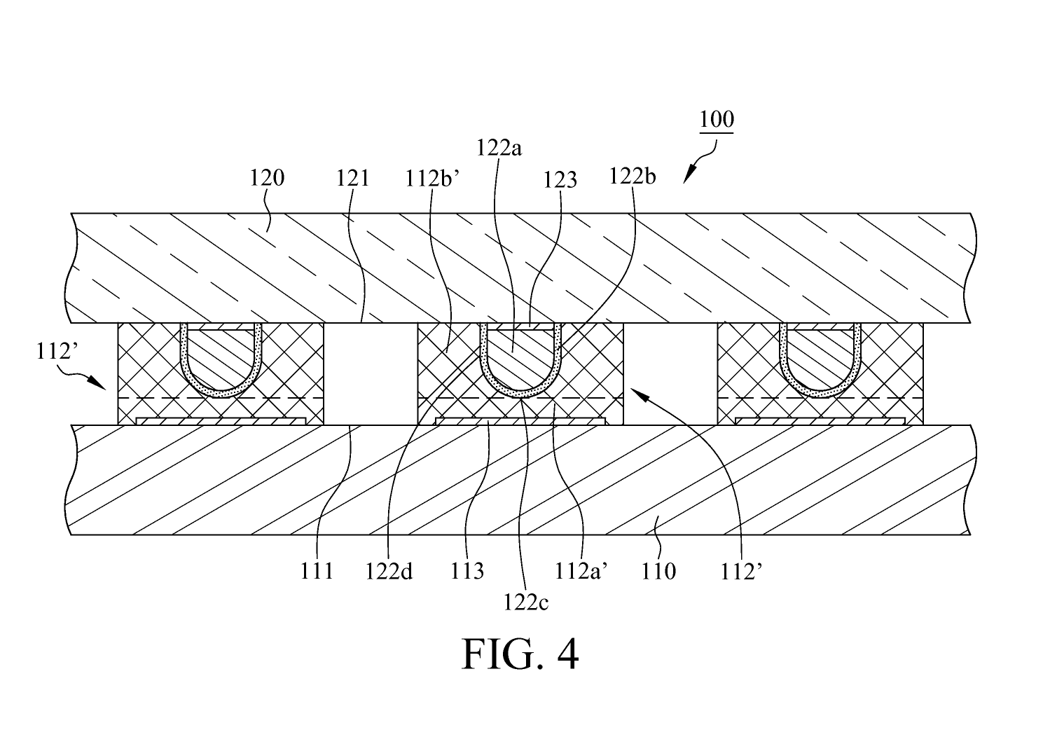

Additionally, referring to FIG. 4, a fourth embodiment of the present invention is disclosed as below. The primary difference between the fourth embodiment and the third embodiment is that the top surface 122c of the second metal bump 122 is in arc shaped.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

What is claimed is:

1. A semiconductor package process at least includes:
providing a first substrate having a first surface and at least one first metal bump formed on the first surface, the at least one first metal bump comprises a bottom portion and a joint portion having a first softening point, the bottom portion is located between the joint portion and the first substrate;
providing a second substrate having a second surface and at least one second metal bump formed on the second surface, the at least one second metal bump comprises a top surface, a lateral surface and a second softening point, wherein the first softening point is smaller than the second softening point;
performing a heating procedure to make the joint portion of the at least one first metal bump become a softened state; and
making the first surface face toward the second surface and laminating the first substrate on the second substrate to make the at least one second metal bump embedded into the joint portion in the softened state to make the top surface and the lateral surface of the at least one second metal bump being clad extendedly by compressing the joint portion in the softened state, wherein the bottom portion in the softened state is located between the at least one second metal bump and the first substrate.

2. The semiconductor package process in accordance with claim 1, wherein the first substrate further comprises a connection layer located between the bottom portion in the softened state and the first substrate.

3. The semiconductor package process in accordance with claim 2, wherein the first substrate further comprises a buffer layer located between bottom portion in the softened state and the connection layer.

4. The semiconductor package process in accordance with claim 1, wherein the at least one second metal bump includes a base layer and a coverage layer covering the base layer.

5. A semiconductor package structure at least includes:
a first substrate having a first surface and at least one first metal bump in a softened state formed on the first surface, the at least one first metal bump in the softened state comprises a bottom portion in the softened state and a joint portion in the softened state, the bottom portion in the softened state is located between the joint portion in the softened state and the first substrate, and the joint portion in the softened state comprises a first softening point; and
a second substrate comprises a second surface facing the first surface and at least one second metal bump formed on the second surface, the at least one second metal bump comprises a top surface, a lateral surface and a second softening point, wherein the first softening point of the joint portion in the softened state is smaller than the second softening point of the at least one second metal bump, the at least one second metal bump is embedded into the joint portion in the softened state of the at least one first metal bump in the softened state to make the top surface and the lateral surface of the at least one second metal bump being clad extendedly by compressing the joint portion in the softened state, the bottom portion in the softened state of the at least one first metal bump in the softened state is located between the at least one second metal bump and the first substrate.

6. The semiconductor package structure in accordance with claim 5, wherein the at least one second metal bump includes a base layer and a coverage layer covering the base layer.

7. The semiconductor package structure in accordance with claim 5, wherein the first substrate further comprises a connection layer located between the bottom portion in the softened state of the at least one first metal bump in the softened state and the first substrate.

8. The semiconductor package structure in accordance with claim 7, wherein the first substrate further comprises a buffer layer located between the bottom portion in the softened state of the at least one metal bump in the softened state and the connection layer.

9. A semiconductor package process at least includes:
providing a first substrate having a first surface and at least one first metal bump formed on the first surface, the at least one first metal bump comprises a bottom portion and a joint portion, the bottom portion is located between the joint portion and the first substrate;
providing a second substrate having a second surface and at least one second metal bump formed on the second surface, the at least one second metal bump comprises a top surface and a lateral surface;
performing a heating procedure to make the joint portion of the at least one first metal bump become a softened state; and
making the first surface face toward the second surface and laminating the first substrate on the second substrate to make the at least one second metal bump embedded into the joint portion in the softened state to make the top surface and the lateral surface of the at least one second metal bump being clad extendedly by compressing the joint portion in the softened state, wherein the bottom portion in the softened state is located between the at least one second metal bump and the first substrate.
